(19) United States
(12) Patent Application Publication
(10) Pub. No.: US 2026/0311752 A1
(43) Pub. Date: Oct. 8, 2026

(54) MEMORY DEVICE WITH ADAPTIVE WRITE CONTROL AND ASSOCIATED METHOD

(71) Applicant: STMicroelectronics International N.V., Geneva (CH)

(72) Inventors: Ashish KUMAR, Ranchi (IN); Shashank GUPTA, Aligarh (IN)

(21) Appl. No.: 19/568,534

(22) Filed: Mar. 16, 2026

Related U.S. Application Data
(60) Provisional application No. 63/782,171, filed on Apr. 2, 2025.

(51) Int. Cl. G11C 11/419

(52) U.S. Cl. CPC G11C 11/419

(57) ABSTRACT

In accordance with various embodiments of the present disclosure, a memory device is provided. In some embodiments, the memory device comprises a plurality of bit cells arranged in a matrix of rows and columns; a plurality of write driver lines, each write driver line selectively connectable to a bit line or a bit-bar line of at least one respective column of bit cells; a plurality of write driver line switches to selectively connect a respective write driver line to ground; a plurality of boost capacitors, each connected to a respective write driver line to selectively inject a negative charge thereon; and a plurality of adaptive control transistors, each connected to a respective write driver line to automatically siphon off some of the negative charge thereon when a voltage applied to a gate of the adaptive control transistor equals or exceeds a threshold voltage of the adaptive control transistor.

### CROSS-REFERENCE TO RELATED APPLICATIONS

This application claims priority to and the benefit of US Provisional Patent Application Serial No. 63/782,171, filed Apr. 2, 2025, and titled “MEMORY DEVICE WITH ADAPTIVE WRITE CONTROL AND ASSOCIATED METHOD,” which is incorporated herein by reference in its entirety.

### FIELD OF THE INVENTION

Example embodiments of the present disclosure relate generally to memory device and, in particular, to write control for memory devices.

### BACKGROUND

Static Random-Access Memories (SRAMs) comprise an array of bit cells that each have a 0 or a 1 state representing stored information. The state of each bit cell can be written (i.e., changed) to store information and can be read to retrieve the stored information. One common type of SRAM is termed 6T SRAM because each bit cell comprises six transistors.

An example SRAM device comprises a plurality of horizontal word lines, each connected to a corresponding row of bit cells, a plurality of vertical bit lines, each connected to a corresponding column of bit cells, and a plurality of vertical bit-bar lines, each connected to a corresponding column of bit cells. Each bit line and its corresponding bit-bar line have opposite states. By controlling the signals on the word lines, the bit lines, and the bit-bar lines, the desired bit cell can be written or read.

Such an example SRAM device also comprises a plurality of write driver lines, each write driver line is selectively connectable to a bit line or a bit-bar line of at least one respective column of bit cells. In addition to controlling the signals on the word lines, the bit lines, and the bit-bar lines, the desired bit cell is written by pulling the write driver line down to 0. With technology scaling, high density 6T SRAMs suffer from stability issues and often use read assist and write assist circuits to ensure stable operation. The most commonly used write assist technique is termed negative bit line. The negative bit line technique uses a plurality of boost capacitors to add a negative charge to the write driver lines, thereby bringing the write driver line voltage below 0 when the write driver lines are pulled down.

The requirement for a negative bit line is higher when the supply voltage is low and the operating temperature is low. Conversely, the requirement for a negative bit line is lower when the supply voltage is high. However, the negative bit line bump (i.e., the difference between the supply voltage and the voltage on the write driver line) increases when the supply voltage increases, and this increase in the difference between the supply voltage and the voltage on the write driver line may cause overstressing of the some of the components of the SRAM and may lead to reliability and oxide breakdown issues.

Applicant has identified many technical challenges and difficulties associated with write operations of SRAM devices. Through applied effort, ingenuity, and innovation, Applicant has solved problems related to write operations of SRAM devices by developing solutions embodied in the present disclosure, which are described in detail below.

### BRIEF SUMMARY

Various embodiments described herein related to memory devices with adaptive write control and associated methods for write control in memory devices.

In accordance with various embodiments of the present disclosure, a memory device is provided. In some embodiments, the memory device comprises a plurality of bit cells arranged in a matrix of rows and columns; a plurality of bit lines, each bit line connected to the bit cells in a respective column of bit cells; a plurality of bit-bar lines, each bit-bar line connected to the bit cells in a respective column of bit cells; a plurality of word lines, each word line connected to the bit cells in a respective row of bit cells; a plurality of write driver lines, each write driver line selectively connectable to a bit line or a bit-bar line of at least one respective column of bit cells; a plurality of write driver line switches to selectively connect a respective write driver line to ground; a plurality of boost capacitors, each boost line capacitor connected to a respective write driver line to selectively inject a negative charge thereon; and a plurality of adaptive control transistors. Each adaptive control transistor is connected to a respective write driver line to automatically siphon off some of the negative charge thereon when a voltage applied to a gate of the adaptive control transistor equals or exceeds a threshold voltage of the adaptive control transistor.

In some embodiments, the memory device comprises a static random access memory device.

In some embodiments, each of the plurality of adaptive control transistors comprise an N-channel metal-oxide semiconductor (NMOS) transistor.

In some embodiments, the voltage applied to the gate of each of the adaptive control transistors is a process-voltage-temperature (PVT)-adjusted operating voltage of the memory device.

In some embodiments, the voltage applied to the gate of each of the adaptive control transistors is a process-voltage-temperature (PVT)-adjusted value of an operating voltage of the memory device minus a voltage delta selected to underdrive the plurality of word lines.

In some embodiments, a voltage applied to each of the plurality of word lines is provided by a read-assist word line underdrive circuit, and the operating voltage of the memory device minus the voltage delta selected to underdrive the plurality of word lines is provided by a replica of the read-assist word line underdrive circuit.

In some embodiments, each of the plurality of write driver line switches comprise a metal-oxide semiconductor (MOS) transistor.

In some embodiments, the voltage applied to the gate of each of the adaptive control transistors is selectively channeled via an adaptive control line from a voltage subtraction unit.

In some embodiments, the memory device further comprises a bleeder switch connected to the adaptive control line to selectively pull the adaptive control line to zero volts at a beginning of each write operation.

In some embodiments, the threshold voltage of each of the adaptive control transistors is selected to limit a difference between the voltage applied to each of the plurality of word lines and the voltage on the write driver lines to limit overstressing of one or more components of the memory device.

In accordance with various embodiments of the present disclosure, a method for adaptive write control of a memory device is provided. In some embodiments, the method comprises injecting a negative charge onto each of a plurality of write driver lines via a plurality of boost capacitors, each boost line capacitor connected to a respective one of the plurality of write driver lines, each write driver line being selectively connectable to one of a plurality of bit lines or one of a plurality of bit-bar lines of at least one respective column of bit cells of a plurality of bit cells arranged in a matrix of rows and columns; and automatically applying a voltage to a gate of each of a plurality of adaptive control transistors, each adaptive control transistor connected to a respective one of the plurality of write driver lines, to siphon off some of the negative charge on each of the plurality of write driver lines when the voltage applied to the gate of each adaptive control transistor equals or exceeds a threshold voltage of the respective adaptive control transistor. Each of the plurality of bit lines and each of the plurality of bit-bar lines are connected to the bit cells in a respective column of bit cells.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 illustrates an example architecture of an example memory device, in accordance with some embodiments of the present disclosure; and

FIG. 2 illustrates an example architecture of an example memory device, in accordance with some alternative embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing memory devices (e.g., SRAM) with adaptive write control (which may also be termed adaptive write assist) that, as the supply or operating voltage increases, the amount of the negative bit line bump is limited by siphoning off some of the negative charge on the write driver lines, thereby reducing the likelihood of reliability and oxide breakdown issues.

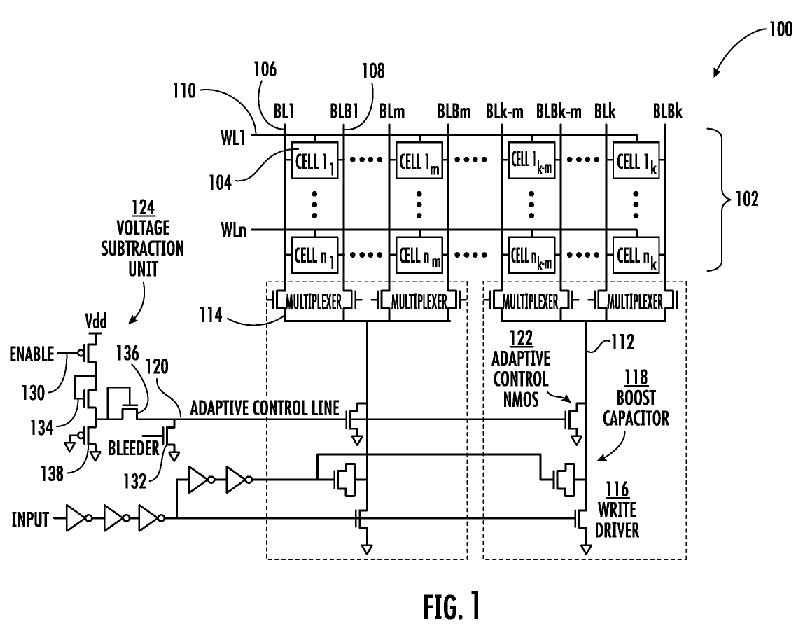

Referring now to FIG. 1, an example architecture of an example memory device is illustrated in accordance with some embodiments of the present disclosure. The memory device (e.g., SRAM) 100 of FIG. 1 comprises a memory array 102 comprising a plurality of bit cells 104 arranged in a plurality of rows (labeled CELL 1₁, …CELL 1ₖ to CELL n₁, …CELL nₖ) and a plurality of columns (labeled CELL 1₁, …CELL n₁ to CELL 1ₖ, …CELL nₖ). A plurality of vertical bit lines 106 (BL1, BLm,…BLk) are each connected to a corresponding column of bit cells 104, and a plurality of vertical bit-bar lines 108 (BLB1, BLBm,…BLBk) are each connected to a corresponding column of bit cells 104. (A bit-bar line may also be referred to as a bit line bar.) Each bit line 106 and its corresponding bit-bar line 108 have opposite states. A plurality of horizontal word lines 110 (WL1, …WLn) are each connected to a corresponding row of bit cells 104. By controlling the signals on the word lines, the bit lines, and the bit-bar lines, the desired bit cell can be written or read.

The memory device 100 of FIG. 1 comprises a plurality of write driver lines 112. Each write driver line 112 is selectively connectable, via a multiplexer 114, to a bit line 106 or a bit-bar line 108 of at least one respective column of bit cells 104. The memory device 100 of FIG. 1 comprises a plurality of write driver line switches 116 to selectively connect a respective write driver line 112 to ground. In the illustrated embodiment, the write driver line switches 116 comprise N-channel metal-oxide semiconductor (NMOS) transistors. The memory device 100 of FIG. 1 comprises a plurality of boost capacitors 118, each connected to a respective write driver line 112 to selectively inject a negative charge thereon to perform the negative bit line write assist technique. As described above, the requirement for a negative bit line is lower when the supply voltage is high, and the increase in the negative bit line bump when the supply voltage increases may cause overstressing of the some of the components of the SRAM and may lead to reliability and oxide breakdown issues.

To address the issue of the negative bit line bump increasing when the supply voltage increases, various embodiments of the present disclosure provide adaptive write control that, as the supply voltage increases, limits the amount of the negative bit line bump by siphoning off some of the negative charge on the write driver lines. As seen in FIG. 1, the memory device 100 comprises a plurality of adaptive control transistors 122. Each adaptive control transistor 122 is connected to a respective write driver line 112. In the illustrated embodiment, each of the plurality of adaptive control transistors 122 comprise an NMOS transistor, with its source connected to the respective write driver line 112, its drain connected to ground, and its gate connected to a voltage subtraction unit 124 via an adaptive control line 120.

An NMOS transistor works by creating a conductive channel between its source and drain terminals when a positive voltage is applied to its gate, allowing electrons to flow through the channel and essentially acting like a switch that can be turned on or off by the gate voltage. The higher the gate voltage, the more current can flow through the channel. A minimum positive voltage on the gate (called the threshold voltage) is required to create a conductive channel and turn the NMOS transistor on.

In various embodiments, the threshold voltage of each of the adaptive control transistors 122 is selected to limit a difference between the voltage applied to each of the plurality of word lines 110 and the voltage on the write driver lines 112 to limit overstressing of the components of the memory device 100.

In the embodiment of FIG. 1, the voltage subtraction unit 124 provides an adjusted version of the supply/operating voltage Vdd of the memory device 100 to the gates of the adaptive control NMOS transistors 122. The voltage subtraction unit 124 comprises a first diode-connected NMOS transistor 134 in series with a second diode-connected NMOS transistor 136. By passing the supply voltage Vdd through the first diode-connected NMOS transistor 134 and the second diode-connected NMOS transistor 136, the voltage provided to the adaptive control NMOS transistors is adjusted for process, voltage, and temperature (PVT). As such, the voltage provided to the adaptive control NMOS transistors may be termed PVT-aware or PVT-adjusted voltage. The two diode-connected NMOS transistors in the voltage subtraction unit are selected to have the same process corners (i.e., fast-slow (FS) or slow-fast (SF)) as the NMOS transistors in the cells 104. In this regard, the voltage provided to the adaptive control NMOS transistors is adjusted for process (i.e., based on the process corners of the transistors). As Vdd varies, so does the voltage provided to the adaptive control NMOS transistors. In this regard, the voltage provided to the adaptive control NMOS transistors is adjusted for voltage. The two diode-connected NMOS transistors in the voltage subtraction unit are affected by temperature in the same way as the NMOS transistors in the cells 104. In this regard, the voltage provided to the adaptive control NMOS transistors is adjusted for temperature. By providing this PVT-adjusted voltage to the adaptive control NMOS transistors, the voltage subtraction unit 124 enables more finely tuned adaptive control of the negative bit line bump.

In various embodiments, as illustrated in FIG. 1, the source of a PMOS transistor 138 is connected to the source of the first diode-connected NMOS transistor 134 and the gate of the second diode-connected NMOS transistor 136. The PMOS transistor 138 stabilizes the adaptive control line voltage quickly, thereby preventing the voltage on the adaptive control line from continuing to increase.

The adaptive control transistors 122 are selected based on their threshold voltage. Specifically, in the embodiment of FIG. 1, the threshold voltage of the adaptive control transistors 122 is selected to be equal to the PVT-adjusted voltage at which it is desirable to begin siphoning off some of the negative charge from the write driver lines. That is, the threshold voltage of each of the adaptive control transistors 122 is selected such that the adaptive control transistors 122 begin siphoning some of the negative charge on the write driver lines 112 when the PVT-adjusted voltage rises to a level at which the negative bit line bump is high enough to overstress the components of the memory device 100.

As the PVT-adjusted voltage increases and reaches a level above which it has been predetermined that the negative bit line bump may start to cause damage to the components (i.e., the PVT-adjusted voltage reaches the threshold voltage of the adaptive control transistors 122), the adaptive control transistors 122 become active and begin siphoning off some of the negative charge on the corresponding write driver lines 112 to ground. As the PVT-adjusted voltage continues to increase, the adaptive control transistors 122 allow more current to flow and more of the negative charge on the write driver lines 112 is siphoned off. In this regard, the adaptive write control of embodiments of the present disclosure automatically limit the negative bit line bump when the PVT-adjusted voltage increases.

As seen in FIG. 1, the voltage subtraction unit 124 of the memory device 100 comprises an enable line 130 to cause the voltage subtraction unit 124 to provide the PVT-adjusted voltage to the adaptive control transistors 122 during each write operation. As seen in FIG. 1, the voltage subtraction unit 124 of the memory device 100 comprises a bleeder switch 132 connected to the adaptive control line 120 to selectively pull the adaptive control line 120 to zero volts at a beginning of each write operation.

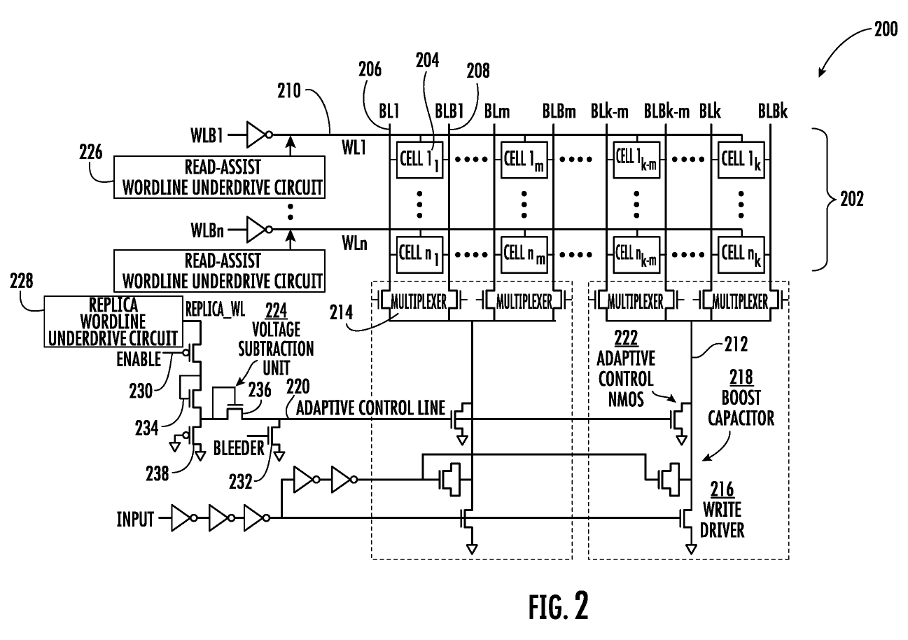

FIG. 2 illustrates an example architecture of an example memory device, in accordance with some alternative embodiments of the present disclosure. FIG. 2 illustrates an alternative embodiment in which an adjusted voltage value is provided to the voltage subtraction unit and to the gates of the adaptive control NMOS transistors, as described further below.

The memory device (e.g., SRAM) 200 of FIG. 2 comprises a memory array 202 comprising a plurality of bit cells 204 (labeled CELL 1, …CELL n) arranged in a plurality of rows and a plurality of columns. A plurality of vertical bit lines 206 (BL1, BLm,…BLk) are each connected to a corresponding column of bit cells 204, and a plurality of vertical bit-bar lines 208 (BLB1, BLBm,…BLBk) are each connected to a corresponding column of bit cells 204. Each bit line 206 and its corresponding bit-bar line 208 have opposite states. A plurality of horizontal word lines 210 (WL1, …WLn) are each connected to a corresponding row of bit cells 204. By controlling the signals on the word lines, the bit lines, and the bit-bar lines, the desired bit cell can be written or read.

The memory device 200 of FIG. 2 comprises a plurality of write driver lines 212. Each write driver line 212 is selectively connectable, via a multiplexer 214, to a bit line 206 or a bit-bar line 208 of at least one respective column of bit cells 204. The memory device 200 of FIG. 2 comprises a plurality of write driver line switches 216 to selectively connect a respective write driver line 212 to ground. In the illustrated embodiment, the write driver line switches 216 comprise NMOS transistors. The memory device 200 of FIG. 2 comprises a plurality of boost capacitors 218, each connected to a respective write driver line 212 to selectively inject a negative charge thereon to perform the negative bit line write assist technique.

It is conventionally known to include a read assist word line underdrive circuit in SRAM devices. Such a read assist word line underdrive circuit 226 is shown in FIG. 2 connected to each word line 210. Such read assist word line underdrive circuits reduce the voltage provided to the word lines from Vdd to (Vdd – ΔV). Reducing the voltage on the word lines by ΔV helps during read operations to keep the bit cells stable (the stored value in the bit cell should not change during a read operation) but can impede write operations as it decreases the difference between the voltage on the word lines and the voltage on the write driver line. The larger ΔV is (i.e., the lower the voltage on the word lines), the more the write operations may be negatively affected. Thus, the larger ΔV is, the less negative voltage we want to siphon off the write driver lines. The value of ΔV is determined by a read assist word line underdrive circuit based on the manufacturing properties (and therefore the speed) of the individual transistors in each bit cell.

The embodiment of FIG. 2 addresses this problem of the effect on write operations by a relatively large ΔV by having a replica of the read assist word line underdrive circuit provide the input to the voltage subtraction unit. In this regard, the voltage value provided to the voltage subtraction unit is the same as the voltage (Vdd – ΔV) on the word lines. Such a replica read assist word line underdrive circuit 228 is shown in FIG. 2 connected to the voltage subtraction unit 224 which selectively provides the voltage from the replica read assist word line underdrive circuit 228 to the adaptive control transistors 222 via the adaptive control line 220.

As ΔV increases (and therefore Vdd – ΔV decreases), less charge is siphoned from the write driver lines, and, as ΔV decreases (therefore Vdd – ΔV increases), more charge is siphoned from the write driver lines. In this regard, decreases in the difference between the voltage on the word lines and the voltage on the write driver line caused by increases in ΔV are not worsened by unnecessarily siphoning negative charge off the write driver lines.

As with the embodiment of FIG. 1, increases or decreases in Vdd will also affect the amount of charge siphoned from the write driver lines in the embodiment of FIG. 2. Essentially, in various embodiments, the voltage applied to the gate of each of the adaptive control transistors is a PVT-adjusted version of the voltage applied to each of the plurality of word lines.

As seen in FIG. 2, the voltage subtraction unit 224 of the memory device 200 comprises an enable line 230 to cause the voltage subtraction unit 224 to provide an adjusted version of the voltage (Vdd – ΔV) on the word lines to the adaptive control transistors 222 during each write operation. The voltage subtraction unit 224 comprises a first diode-connected NMOS transistor 234 in series with a second diode-connected NMOS transistor 236. By passing the voltage (Vdd – ΔV) on the word lines through the first diode-connected NMOS transistor 234 and the second diode-connected NMOS transistor 236, the voltage provided to the adaptive control NMOS transistors is adjusted for process, voltage, and temperature (PVT). As such, the voltage provided to the adaptive control NMOS transistors may be termed PVT-aware or PVT-adjusted voltage. The two diode-connected NMOS transistors in the voltage subtraction unit are selected to have the same process corners (i.e., fast-slow (FS) or slow-fast (SF)) as the NMOS transistors in the cells 204. In this regard, the voltage provided to the adaptive control NMOS transistors is adjusted for process (i.e., based on the process corners of the transistors). As Vdd – ΔV varies, so does the voltage provided to the adaptive control NMOS transistors. In this regard, the voltage provided to the adaptive control NMOS transistors is adjusted for voltage. The two diode-connected NMOS transistors in the voltage subtraction unit are affected by temperature in the same way as the NMOS transistors in the cells 204. In this regard, the voltage provided to the adaptive control NMOS transistors is adjusted for temperature. By providing this PVT-adjusted voltage to the adaptive control NMOS transistors, the voltage subtraction unit 224 enables more finely tuned adaptive control of the negative bit line bump. As seen in FIG. 2, the voltage subtraction unit 224 of the memory device 200 comprises a bleeder switch 232 connected to the adaptive control line 220 to selectively pull the adaptive control line 220 to zero volts at a beginning of each write operation.

In various embodiments, as illustrated in FIG. 2, the source of a PMOS transistor 238 is connected to the source of the first diode-connected NMOS transistor 234 and the gate of the second diode-connected NMOS transistor 236. The PMOS transistor 238 stabilizes the adaptive control line voltage quickly, thereby preventing the voltage on the adaptive control line from continuing to increase.

In various embodiments of the present disclosure, limiting the negative bit line bump at higher voltages helps ensure reliable operation of a memory device over a broad voltage range.

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of memory device, such as any form of SRAM memory device.

Within the appended claims, unless the specific term “means for” or “step for” is used within a given claim, it is not intended that the claim be interpreted under 35 U.S.C. 112, paragraph 6.

What is claimed is:

1. A memory device comprising:
a plurality of bit cells arranged in a matrix of rows and columns;
a plurality of bit lines, each bit line connected to the bit cells in a respective column of bit cells;
a plurality of bit-bar lines, each bit-bar line connected to the bit cells in a respective column of bit cells;
a plurality of word lines, each word line connected to the bit cells in a respective row of bit cells;
a plurality of write driver lines, each write driver line selectively connectable to a bit line or a bit-bar line of at least one respective column of bit cells;
a plurality of write driver line switches to selectively connect a respective write driver line to ground;
a plurality of boost capacitors, each boost line capacitor connected to a respective write driver line to selectively inject a negative charge thereon; and
a plurality of adaptive control transistors, each adaptive control transistor connected to a respective write driver line to automatically siphon off some of the negative charge thereon when a voltage applied to a gate of the adaptive control transistor equals or exceeds a threshold voltage of the adaptive control transistor.

2. The memory device of claim 1, wherein the memory device comprises a static random access memory device.

3. The memory device of claim 1, wherein each of the plurality of adaptive control transistors comprise an N-channel metal-oxide semiconductor (NMOS) transistor.

4. The memory device of claim 1, wherein the voltage applied to the gate of each of the adaptive control transistors is a process-voltage-temperature (PVT)-adjusted operating voltage of the memory device.

5. The memory device of claim 1, wherein the voltage applied to the gate of each of the adaptive control transistors is a process-voltage-temperature (PVT)-adjusted value of an operating voltage of the memory device minus a voltage delta selected to underdrive the plurality of word lines.

6. The memory device of claim 5, wherein a voltage applied to each of the plurality of word lines is provided by a read-assist word line underdrive circuit; and
wherein the operating voltage of the memory device minus the voltage delta selected to underdrive the plurality of word lines is provided by a replica of the read-assist word line underdrive circuit.

7. The memory device of claim 1, wherein each of the plurality of write driver line switches comprise a metal-oxide semiconductor (MOS) transistor.

8. The memory device of claim 1, wherein the voltage applied to the gate of each of the adaptive control transistors is selectively channeled via an adaptive control line from a voltage subtraction unit; and
wherein the voltage subtraction unit comprises a first diode-connected N-channel metal-oxide semiconductor (NMOS) transistor in series with a second diode-connected NMOS transistor.

9. The memory device of claim 8, further comprising a P-channel metal-oxide semiconductor (PMOS) transistor to stabilize the adaptive control line voltage, wherein a source of the PMOS transistor is connected to a source of the first diode-connected NMOS transistor and to a gate of the second diode-connected NMOS transistor.

10. The memory device of claim 8, further comprising a bleeder switch connected to the adaptive control line to selectively pull the adaptive control line to zero volts at a beginning of each write operation.

11. The memory device of claim 1, wherein the threshold voltage of each of the adaptive control transistors is selected to limit a difference between the voltage applied to each of the plurality of word lines and the voltage on the write driver lines to limit overstressing of one or more components of the memory device.

12. A method for adaptive write control of a memory device, the method comprising:
injecting a negative charge onto each of a plurality of write driver lines via a plurality of boost capacitors, each boost line capacitor connected to a respective one of the plurality of write driver lines, each write driver line being selectively connectable to one of a plurality of bit lines or one of a plurality of bit-bar lines of at least one respective column of bit cells of a plurality of bit cells arranged in a matrix of rows and columns; and
automatically applying a voltage to a gate of each of a plurality of adaptive control transistors, each adaptive control transistor connected to a respective one of the plurality of write driver lines, to siphon off some of the negative charge on each of the plurality of write driver lines when the voltage applied to the gate of each adaptive control transistor equals or exceeds a threshold voltage of the respective adaptive control transistor;
wherein each of the plurality of bit lines and each of the plurality of bit-bar lines are connected to the bit cells in a respective column of bit cells.

13. The method of claim 12, wherein the memory device comprises a static random access memory device.

14. The method of claim 12, wherein each of the plurality of adaptive control transistors comprise an N-channel metal-oxide semiconductor (NMOS) transistor.

15. The method of claim 12, wherein the voltage applied to the gate of each of the adaptive control transistors is a process-voltage-temperature (PVT)-adjusted operating voltage of the memory device.

16. The method of claim 12, wherein the voltage applied to the gate of each of the adaptive control transistors is a process-voltage-temperature (PVT)-adjusted operating voltage of the memory device minus a voltage delta selected to underdrive a plurality of word lines, each word line connected to the bit cells in a respective row of bit cells.

17. The method of claim 16, wherein a voltage applied to each of the plurality of word lines is provided by a read-assist word line underdrive circuit; and
wherein the operating voltage of the memory device minus the voltage delta selected to underdrive the plurality of word lines is provided by a replica of the read-assist word line underdrive circuit.

18. The method of claim 12, wherein the voltage applied to the gate of each of the adaptive control transistors is selectively channeled via an adaptive control line from a voltage subtraction unit;
wherein the wherein the voltage subtraction unit comprises a first diode-connected N-channel metal-oxide semiconductor (NMOS) transistor in series with a second diode-connected NMOS transistor; and
wherein the method further comprises stabilizing the adaptive control line voltage by connecting a source of a P-channel metal-oxide semiconductor (PMOS) transistor to a source of the first diode-connected NMOS transistor and to a gate of the second diode-connected NMOS transistor.

19. The method of claim 18, further comprising selectively pulling each of the adaptive control lines to zero volts at a beginning of each write operation.

20. The method of claim 12, wherein the threshold voltage of each of the adaptive control transistors is selected to limit a difference between the voltage applied to each of a plurality of word lines and the voltage on the write driver lines to limit overstressing of one or more components of the memory device;
wherein each word line is connected to the bit cells in a respective row of bit cells.
